(19) United States
(12) Patent Application Publication
(10) Pub. No.: US 2012/0312575 A1
(43) Pub. Date: Dec. 13, 2012

(54) Electric Component and Method of Making the Same

(76) Inventor: Tien-Ming Chou, Taichung City (TW)

(21) Appl. No.: 13/156,857

(22) Filed: Jun. 9, 2011

(51) Int. Cl. H05K 5/00; B29C 45/14

(52) U.S. Cl. 174/50; 264/272.14

(57) ABSTRACT

A method of making an electric component includes: (a) stamping a metal stock plate to form a plurality of conductive terminals that are partially connected to an excess portion of the metal stock plate; (b) bending each of the conductive terminals to form a bended portion; and (c) forming a housing body over the conductive terminals by insert molding the bended portions of the conductive terminals in the housing body, each of the conductive terminals having an internal portion that is disposed within the housing body and that includes the bended portion, and an external portion that extends out of the housing body and that is connected to the excess portion.

### BACKGROUND OF THE INVENTION

1. Field of the Invention

This invention relates to an electric component, more particularly to an electric component and a method of making the same.

2. Description of the Related Art

Referring to FIG. 1 or FIG. 2, a conventional electric component 1 includes a housing body 11 and at least two conductive terminals 12 made of metal. When the electric component 1 is used as a ball switch, it further includes a ball (not shown) received in an upper trench of the housing body 11. When the ball contacts the two conductive terminals 12 simultaneously, the electric component 1 produces a switching signal. Each of the conductive terminals 12 includes an internal portion 121 and an external portion 122 that extends from the internal portion 121 to extend out of the housing body 11. A free end 123 of the external portion 122 has a bottom face adapted to electrically connect with a circuit of a circuit board 2.

The electric component 1 is formed by the following steps.

In step 1, a metal stock plate 12′ is stamped to form a plurality of conductive terminals 12 that are partially connected to an excess portion of the metal stock plate 12′.

In step 2, the housing body 11 is formed by insert molding the internal portions 121 of the conductive terminals 12 in the housing body 11 using a mold (not shown). The remaining parts of the conductive terminals 12 and the excess portion of the metal stock plate 12′ are exposed out of the housing body 11.

In step 3, the excess portion of the metal stock plate 12′ is cut off from the conductive terminals 12.

In step 4, the remaining parts of the conductive terminals 12 are bent to form the external portions 122.

In order to place the free ends 123 of the conductive terminals 12 in parallel with the circuit board 2, the external portions 122 are commonly bent in a manner shown in FIG. 1 or 2.

Although the aforesaid method steps can achieve an effect of coupling the conductive terminals 12 with the housing body 11, the resulting structural strength is weak. This is because the straight parts of the conductive terminals 12 embedded within the housing body 11 are relatively short. On the other hand, because relatively long bended parts of the conductive terminals 12 are exposed, they are likely to deform due to an external force during transport.

Referring to FIG. 3, another conventional electric component 3 also includes a housing body 31 and at least two conductive terminals 32 made of metal. Each of the conductive terminals 32 is in a form of a straight strip, and has an internal portion 321 disposed within the housing body 31 and an external portion 322 connectable to the circuit board 2. The external portion 322 of each conductive terminal 32 is not bent, and can be directly disposed on the circuit board 2.

However, the structural strength of the electric component 3 is also weak because of the short embedded straight sections of the conductive terminals 32. In addition, the electric component 3 having the non-bent conductive terminals 32 can only be used for a circuit board 2 which has a connector mounting hole as shown in FIG. 3.

### SUMMARY OF THE INVENTION

Therefore, an object of the present invention is to provide an electric component and a method of making the same that can overcome the aforesaid drawbacks associated with the prior art.

According to the first aspect of this invention, method of making an electric component comprises:

(a) stamping a metal stock plate to form a plurality of conductive terminals that are partially connected to an excess portion of the metal stock plate;

(b) bending each of the conductive terminals to form a bended portion; and

(c) forming a housing body over the conductive terminals by insert molding the bended portions of the conductive terminals in the housing body, each of the conductive terminals having an internal portion that is disposed within the housing body and that includes the bended portion, and an external portion that extends out of the housing body and that is connected to the excess portion.

According to the second aspect of this invention, an electric component comprises:

a housing body; and

a plurality of conductive terminals insert molded in the housing body, each of the conductive terminals including an internal portion that is disposed within the housing body and that has a bended portion, and an external portion that extends from the internal portion to extend out of the housing body.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is a flowchart illustrating a method of making a conventional electric component;

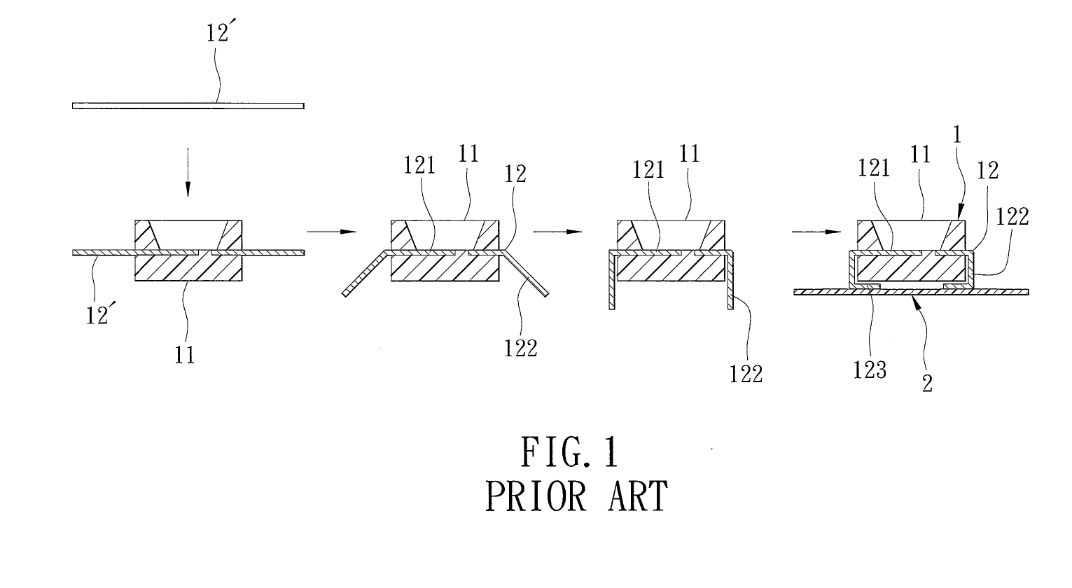

FIG. 2 is a cross-sectional view showing another conventional electric component produced by the method illustrated in FIG. 1;

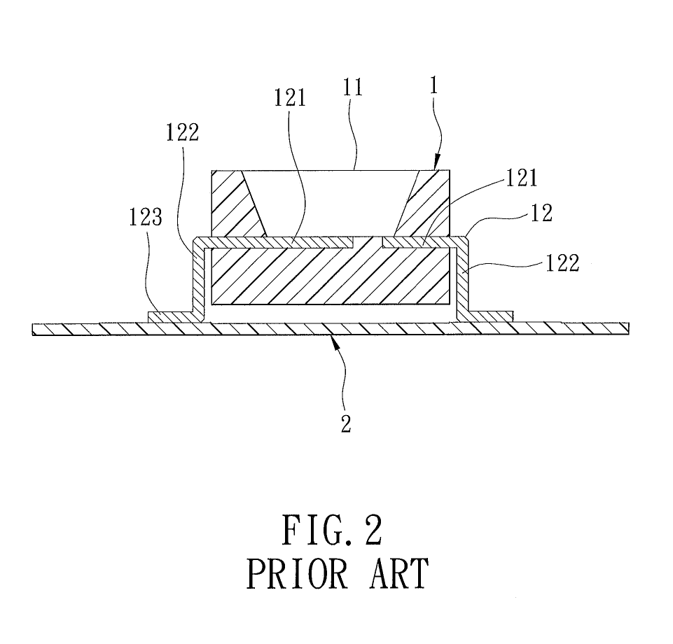

FIG. 3 is a cross-sectional view showing still another conventional electric component;

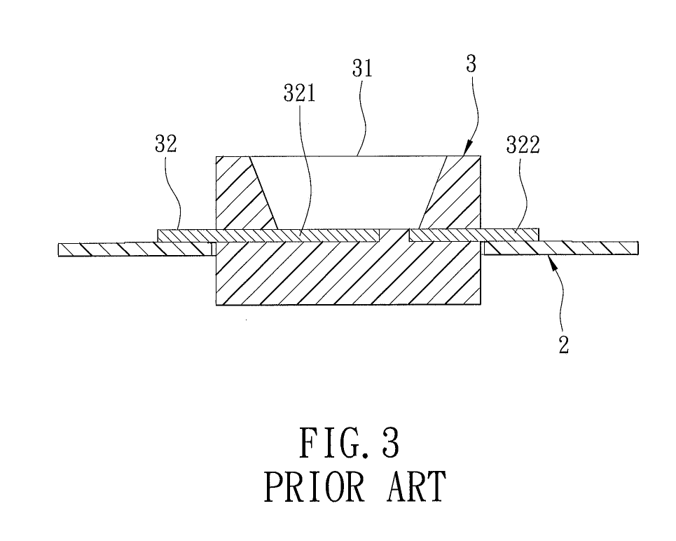

FIG. 4 is a cross-sectional view showing how conductive terminals are formed according to a method of this invention;

FIG. 5 is a perspective view of an electric component according to this invention;

FIG. 6 is a cross-sectional view of the electric component according to this invention; and

FIG. 7 is a flow chart showing a method of making an electric component according to this invention.

### DETAILED DESCRIPTION OF THE PREFERRED EMBODIMENT

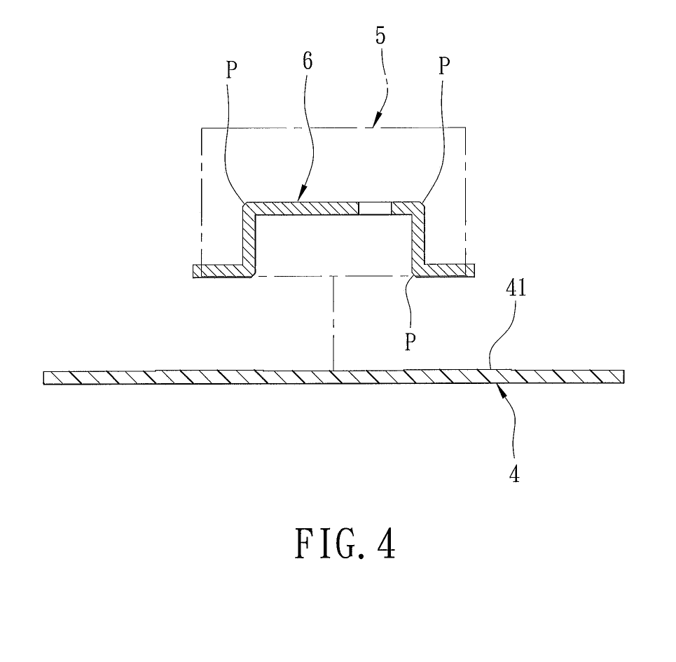

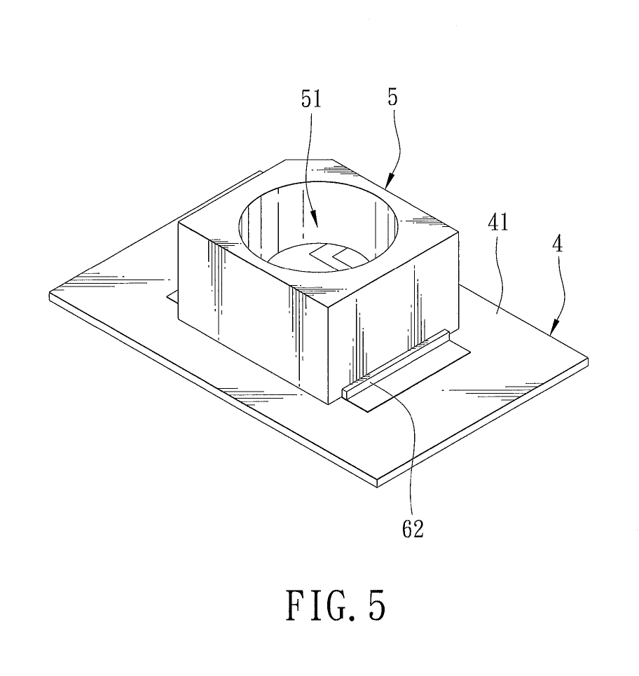

Referring to FIGS. 4 to 6, the preferred embodiment of an electric component according to this invention is mounted on an upper surface 41 of a circuit board 4. Preferably, the electric component is used as a ball switch, and comprises a housing body 5 and two conductive terminals 6. The housing body 5 has a receiving space 51 to receive a ball (not shown) rollable within the receiving space 51 to bridge or unbridge the conductive terminals 6.

The housing body 5 is formed by injection molding.

Each of the conductive terminals 6 is insert molded in the housing body 5, and has an internal portion 61 and an external portion 62. The internal portion 61 is disposed within the housing body 5, and includes a bended portion that has two bends (P). The external portion 62 extends from the internal portion 61 to extend out of the housing body 5. The internal portion 61 has a length longer than that of the external portion 62. Preferably, the length of the external portion 62 is less than 2 mm. The external portion 62 has a lower surface that is co-planar with a bottom surface of the housing body 5. Therefore, when the electric component is disposed on the circuit board 4, each external portion 62 can contact intimately the upper surface 41 of the circuit board 4.

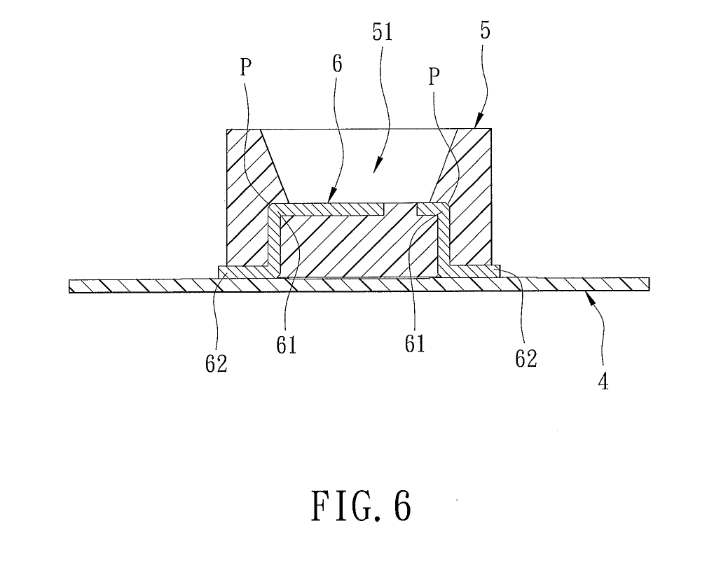

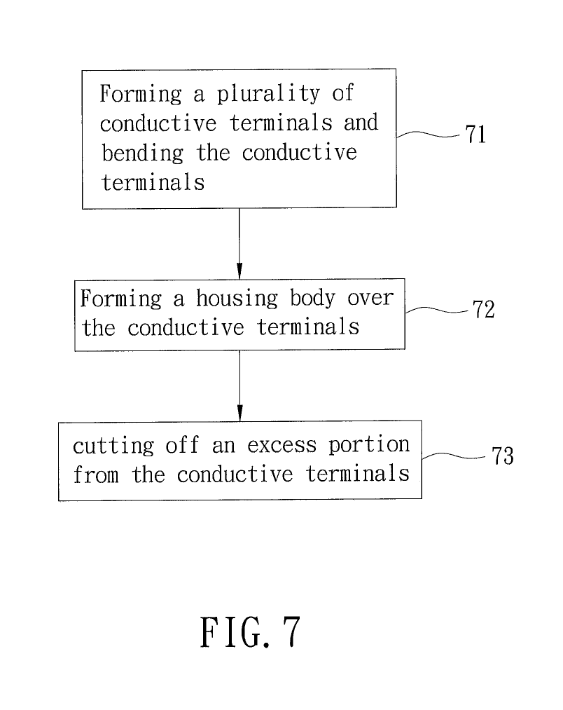

Referring to FIGS. 6 and 7, the preferred embodiment of the electric component according to this invention is made by the following steps.

In step 71, a metal stock plate is stamped to form a plurality of the conductive terminals 6 that are partially connected to an excess portion of the metal stock plate. During the stamping process, each of the conductive terminals 6 is bent to form the bended portion having the bends (P).

In step 72, the housing body 5 is formed over the conductive terminals 6 by insert molding the bended portions of the conductive terminals 6 in the housing body 5. During the insert molding, the bended portions of the conductive terminals 6 are placed within a mold cavity, and the housing body 5 is formed over the bended portions by injection molding. After the step 72, each internal portion 61, which includes the bended portion, is disposed within the housing body 5. Each external portion 62 extends out of the housing body 5, and is connected to the excess portion of the metal stock plate.

In step 73, the excess portion of the metal stock plate is cut off from the external portions 62 of the conductive terminals 6.

Because the internal portions 61 of the conductive terminals 6 have two bends and are disposed within the housing body 5 with a relatively long length, and because the external portions 62 are not bent and are extremely short, compared to the prior art, the internal portions 61 can have an increased coupling strength with the housing body 5, and the external portions 62 are less susceptible to deformation.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

What is claimed is:

1. A method of making an electric component, comprising:
(a) stamping a metal stock plate to form a plurality of conductive terminals that are partially connected to an excess portion of the metal stock plate;
(b) bending each of the conductive terminals to form a bended portion; and
(c) forming a housing body over the conductive terminals by insert molding the bended portions of the conductive terminals in the housing body, each of the conductive terminals having an internal portion that is disposed within the housing body and that includes the bended portion, and an external portion that extends out of the housing body and that is connected to the excess portion.

2. The method of claim 1, further comprising, after step (c), a step of cutting off the excess portion from the external portions of the conductive terminals.

3. The method of claim 1, wherein the bended portion includes two bends.

4. The method of claim 1, wherein the housing body is formed by injection molding.

5. An electric component, comprising:
a housing body; and
a plurality of conductive terminals insert molded in said housing body, each of said conductive terminals including an internal portion that is disposed within said housing body and that has a bended portion, and an external portion that extends from said internal portion to extend out of said housing body.

6. The electric component of claim 5, wherein said internal portion has a length longer than that of said external portion.

7. The electric component of claim 6, wherein the length of said external portion is less than 2 mm.

8. The electric component of claim 5, wherein said external portion has a lower surface that is co-planar with a bottom surface of said housing body.

9. The electric component of claim 5, wherein said bended portion has two bends.
